(19) United States
(12) Patent Application Publication
(10) Pub. No.: US 2026/0128067 A1
(43) Pub. Date: May 7, 2026

(54) ELECTRONIC DEVICE COMPRISING A MEMORY ELEMENT

(71) Applicant: STMicroelectronics International N.V., Geneva (CH)

(72) Inventor: Olivier WEBER, Grenoble (FR)

(73) Assignee: STMicroelectronics International N.V., Geneva (CH)

(21) Appl. No.: 19/371,937

(22) Filed: Oct. 28, 2025

(30) Foreign Application Priority Data
Nov. 7, 2024 (FR) FR2412188

(51) Int. Cl. G11C 5/06; H10B 63/00; H10B 63/10; H10N 70/00

(52) U.S. Cl. CPC G11C 5/063; H10B 63/10; H10B 63/34; H10N 70/021; H10N 70/8828

(57) ABSTRACT

The present disclosure relates to a memory device including a plurality of memory cells arranged in an array with word and bit lines. Each cell includes a memory element made of a phase-change material and two transistors connected by their first conduction nodes, themselves connected to a first terminal of the element. The elements of a bit line are connected by their second terminals. Both transistors of a word line are connected by their gates. Each cell is connected to two source lines, respectively, connected to the two second nodes of the transistors. The cells of a word line are connected to the two source lines and the cells of two consecutive word lines being connected to a common source line. Each transistor is disposed in and on a pair of two fins disposed in a semiconductor substrate.

### CROSS-REFERENCE TO PRIORITY APPLICATIONS

This application claims the priority benefit of French patent application number FR2412188, filed on November 7, 2024, entitled “Dispositif électronique comprenant un circuit mémoire” which is hereby incorporated by reference to the maximum extent allowable by law.

### BACKGROUND

### Technical Field

The present description relates generally to electronic devices and more particularly to electronic devices including a memory circuit.

### Description of the Related Art

Electronic devices include both memory circuits and logic circuits. Here is more particularly of interest electronic devices including memory circuits, referred to as memory devices, including memory elements arranged in array, each memory element being associated to one or more selecting transistors. This transistor is used to separately program, erase, or read each memory element.

It would be desirable to improve, at least in part, some aspects of the known electronic devices.

### BRIEF SUMMARY

To this end, one embodiment provides a memory device including a plurality of memory cells arranged in an array with word lines and bit lines, each memory cell including a memory element made of a phase-change material and two fin field-effect transistors for selecting the memory element, each transistor including first and second conduction nodes and a gate, the memory element including two terminals, wherein:

both transistors of a same memory cell are connected to each other by their first conduction nodes, said first conduction nodes being in turn connected to a first terminal of the memory element; the memory elements of a same bit line are all connected to each other by their second terminals; both transistors of memory cells of a same word line are all connected to each other, by their gates; each memory cell is connected to two source lines, the two source lines being connected to the two second conduction nodes of the transistors of the memory cell, respectively, the memory cells of a same word line being connected to the same two source lines, and the memory cells of two consecutive word lines being connected to a common source line; and each transistor is disposed in and on a pair of two parallel and neighboring fins disposed in a semiconductor substrate.

According to an embodiment, the transistors of the memory cells of a same bit line are disposed on and in a same pair of two fins.

According to an embodiment, the fins of the same pair are spaced from 20 nm to 25 nm apart, for example approximately 22 nm apart.

According to an embodiment, the fin pairs, in and on which are disposed the memory cells of two consecutive bit lines, are spaced from 60 nm to 65 nm apart, for example approximately 62 nm apart.

According to an embodiment, the phase-change material is made of an alloy of germanium, antimony, and tellurium.

According to an embodiment, within each memory cell, the memory element is separated from the transistors by an interconnecting stack.

According to an embodiment, each memory element is connected to the first conduction nodes of both transistors of the same memory cell through a conductive via passing through the interconnecting stack.

According to an embodiment, the memory element includes a heating metal resistive element disposed under the phase-change material and controlling this same material.

According to an embodiment, the source lines are, in tope view, parallel to word lines.

According to an embodiment, the fins are disposed, in a first region of the semiconductor substrate,

the device further including other fins, regularly spaced, disposed in a second region of the semiconductor substrate.

Another embodiment provides a method for manufacturing a device including a plurality of memory cells arranged in an array with word lines and bit lines, each memory cell including a memory element made of a phase-change material and two fin field-effect transistors for selecting the memory element, each transistor including first and second conduction nodes and a gate, the memory element including two terminals, wherein:

both transistors of a same memory cell are connected to each other by their first conduction nodes, said first conduction nodes being in turn connected to a first terminal of the memory element;

the memory elements of a same bit line are all connected to each other by their second terminals;

both transistors of the memory cells in a same word line are all connected to each other, by their gates;

each memory cell is connected to two source lines, the two source lines being connected to two second conduction nodes of the transistors of the memory cell, respectively, the memory cells of a same word line being connected to the same two source lines, and the memory cells of two consecutive word lines being connected to a common source line,

the method including the steps of:

forming fins in a semiconductor substrate, fins being formed by pairs; epitaxially forming a semiconductive layer; and doping the semiconductive layer so as to form regions among which first regions correspond to source regions, and second regions correspond to drain regions, a drain region being common to both transistors of the same memory cell and a source region being common to two transistors of two neighboring memory cells.

According to an embodiment, the formation of the fins is carried out in a first region of the semiconductor substrate,

the method further including, during the fins formation step, the formation of further regularly spaced fins in a second region of the semiconductor substrate.

According to an embodiment, the method includes for selecting a memory cell of a first word line and a first bit line:

applying a first non-zero potential on the first bit line and a zero potential on the other bit lines;

applying a second non-zero potential on the first word line and a zero potential on the other word lines;

applying a zero potential to the two source lines connected to the memory cells of the first word line and a third non-zero potential to the other source lines.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 is an example electronic circuit in a memory device including several memory cells of the phase-change-memory type;

FIG. 2 is an example electronic circuit in a memory device including several memory cells of the phase-change-memory type according to one embodiment;

FIG. 3A, FIG. 3B, FIG. 3C, FIG. 3D, and FIG. 3E are schematic and partial views of an example memory device shown in FIG. 2;

FIG. 4A and FIG. 4B are schematic and partial views of another example memory device shown in FIG. 2; and

FIG. 5A, FIG. 5B, FIG. 5C, and FIG. 5D are schematic and partial views illustrating steps within an example method for manufacturing the memory device illustrated in FIGS. 3A-3E and in FIGS. 4A-B.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, ”top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10% or 10°, and preferably within 5% or 5°.

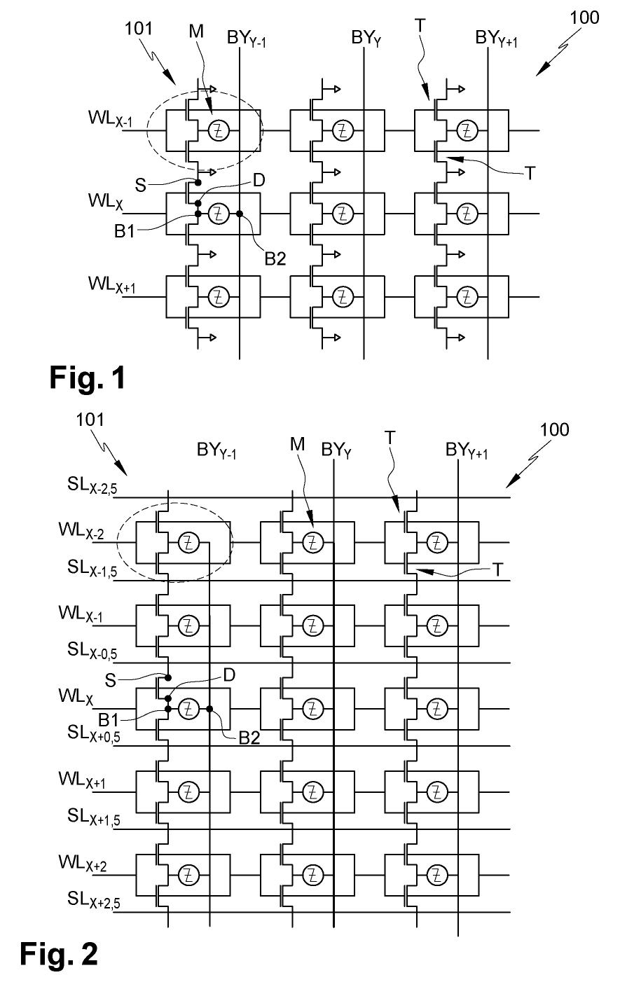

FIG. 1 is an example electronic circuit in a memory device 100 including several memory cells 101 of the phase-change-memory type.

For example, device 100 is an electronic chip.

For example, memory device 100 includes several cells 101 arranged within an array including rows and columns. In the example shown in FIG. 1, the rows in device 100 are referred to as word lines WL and the columns in device 100 are referred to as bit lines BL. As an example, a memory cell is thus formed at the crossing of a bit line and a word line.

By way of example, the device 100 includes a number of word lines higher than 3, for example higher than 100, e.g., in the order of 512. In FIG. 1, only three word lines are illustrated and labelled WLₓ₋₁, WLₓ et WLₓ₊₁.

As an example, the device 100 includes a number of bit lines higher than 3, for example higher than 500, e.g., in the order of 2432. In FIG. 1, only three bit lines are illustrated and labelled BL_{y-1}, BL_{y} et BL_{y+1}.

Each memory cell 101 includes a memory cell M including a first and a second terminal, and two transistors T, including each a first conduction node D, for example a drain, a second conduction node S, for example a source, and a gate. In the memory device 100, both transistors T of each cell 101 have their drains connected to each other. In addition, in the memory device 100, both transistors T of each cell 101 have their sources connected to each other.

For example, in the memory device 100, the sources S of the transistors T are all set to a same potential, e.g., a zero potential.

By way of example, the first terminal of each memory cell M is connected to the drains D of transistors of its memory cell 101.

As an example, the second terminal of the memory cells M of the memory cells 101 of a same bit line BL are connected to each other.

In such a device, when a memory cell 101 is selected, for example the cell of the bit line BL_{y} and word line WLₓ, one comes applying a first non-zero potential to the bit line BL_{y} and a second non-zero potential to the word line WLₓ, so that both transistors of the selected memory cell are turned ON.

Applying the first potential to the bit line BL_{y} causes, in the set of the transistors of the memory cells of the bit line BL_{y}, a high voltage to be applied between the drain D and the source S of the OFF transistors, which causes leakage current within these transistors.

FIG. 2 is an example electronic circuit in a memory device 200 including several cells 101 of the phase-change-memory type according to one embodiment.

More particularly, the device 200 is similar to the device 100 illustrated in FIG. 1 with the difference that the sources S of transistors are connected to source lines SL.

In the embodiment shown in FIG. 2, both transistors of each memory cell 101 are connected to two different source lines. The memory cells of a same word line WL are connected, via both transistors it includes, to the same two source lines SL.

By way of example, the memory cell 101, located at the crossing of the bit line BL_{y} and the word line WLₓ, is connected, via a first transistor, to a source line SL_{x-0,5}, and is connected, via another transistor, to a source line SL_{x+0,5}.

In the embodiment shown in FIG. 2, each source line is connected to the memory cells 101 of two consecutive word lines WL. In other words, the memory cells of two consecutive word lines are connected to a common source line.

As an example, the source line SL_{x+0,5} is connected to a transistor of each memory cell of the word line WLₓ, and to a transistor of each memory cell of the word line WLₓ₊₁.

In such a device, and as that was described with FIG. 1, when a memory cell 101 is selected, for example the cell of the bit line BL_{y} and the word line WLₓ, one comes applying a first potential to the bit line BL_{y} and a second potential to the word line WLₓ, so that both transistors of the selected memory cell are turned ON.

In such a device, and unlike what has been described in relation with FIG. 1, one provides applying a zero potential to two source lines connected to the selected memory cell, and a non-zero third potential to all other source lines SL.

Thus, if the cell of the bit line BL_{y} and the word line WLₓ is selected, one provides applying a zero potential to the source lines SL_{x-0,5}and SL_{x+0,5}, and the third potential to all other source lines. Selectively applying a third potential, or a zero potential, to the source lines allows the voltage across some non-selected transistors to be decreased, thereby decreasing the leakage current through these transistors.

By way of example, to select the memory cell of the bit line BL_{y} and the word line WLₓ, one applies to the bit line BL_{y} a potential of approximately 2.85 V, and to the word line WLₓ a potential of approximately 1.5 V as the other bit lines and word lines are set at a potential of 0 V. In this example, one further applies to the source lines SL_{x-0,5} and SL_{x+0,5} a zero potential as the other source lines have a potential of 1 V.

Thus, along the selected bit line BL_{y}, both transistors of the memory cell of the word line WLₓ are turned ON, the transistors of memory cells adjacent to the selected memory cell, connected to the source lines SL_{x-0,5} and SL_{x+0,5}, are OFF, and have, between the source S and drain D, a voltage of 2.85 V, and the other transistors are OFF, and have, between the source S and drain D, a voltage of 1.85 V.

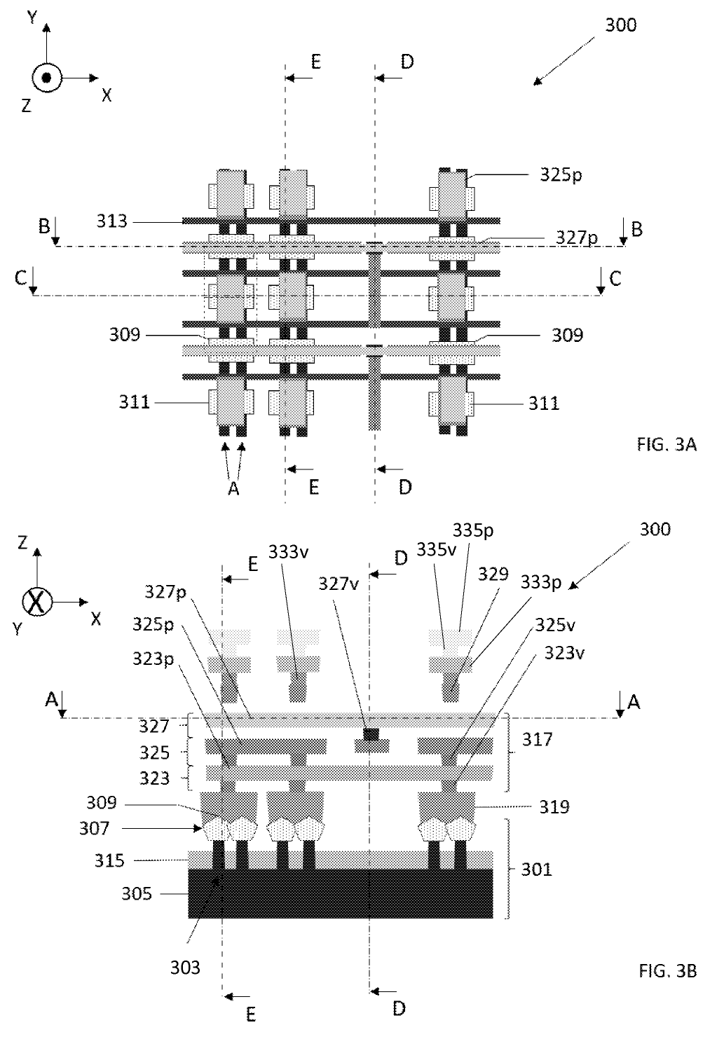

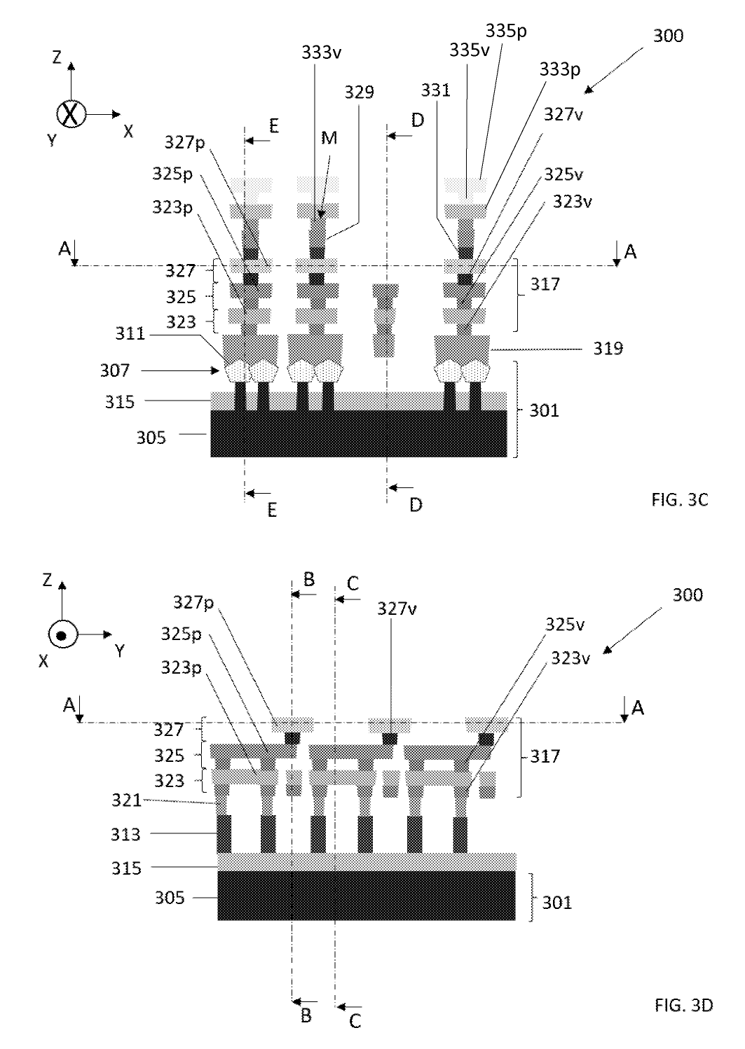

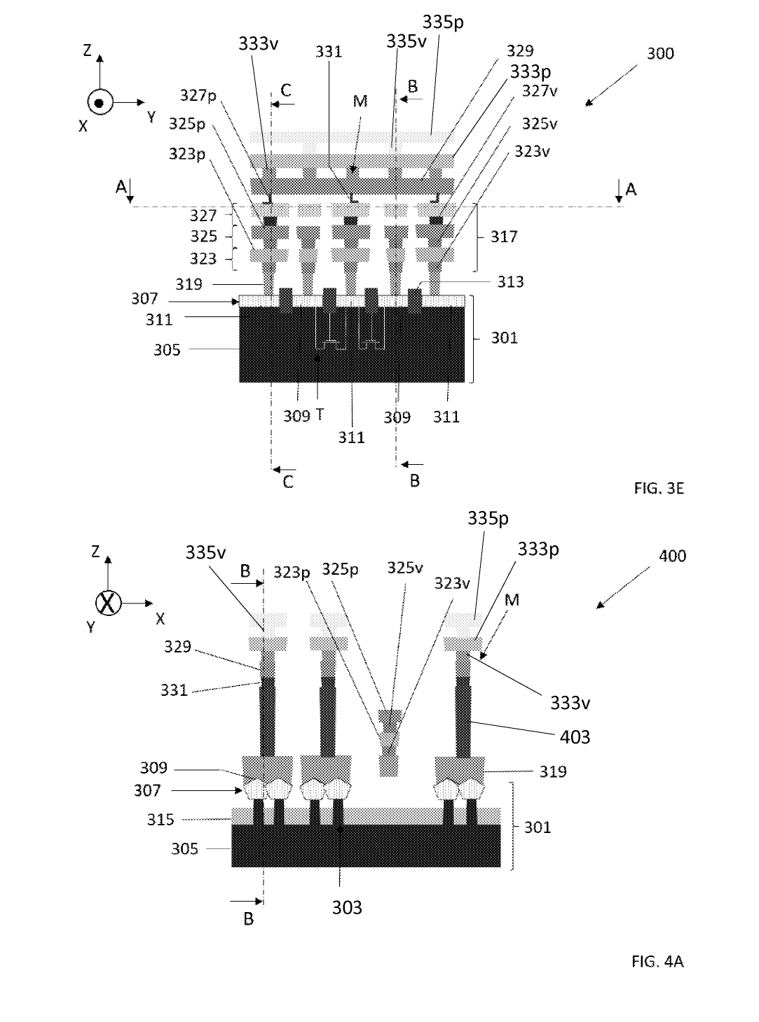

FIG. 3A, FIG. 3B, FIG. 3C, FIG. 3D, and FIG. 3E are schematic and partial views of an example 300 of the memory device shown in FIG. 2.

FIG. 3A is a section view along the horizontal section plane AA shown in FIGS. 3B, 3C, 3D, and 3E. FIG. 3B is a section view along the section plane BB shown in FIGS. 3A, 3D, and 3E. FIG. 3C is a section view along the section plane CC shown in FIGS. 3A, 3D, and 3E. FIG. 3D is a section view along the section plane DD shown in FIGS. 3A, 3B, and 3C. FIG. 3E is a section view along the section plane EE shown in FIGS. 3A, 3B, and 3C.

The device 300 is illustrated in a direct 3D coordinate system XYZ, FIG. 3A corresponding to a view in a plane XY of the system, FIGS. 3B and 3C corresponding each to a view in a plane XZ of the system, and FIGS. 3D and 3E corresponding each to a view in a plane YZ of the system.

Device 300 includes a semiconductor substrate 301. As an example, the substrate 301 is made of silicon or is silicon-based.

For example, the substrate 301 includes a semiconductor layer 305 formed in a bottom part of the substrate 301. Further, the substrate 301 includes fins 303 formed within the layer 305, from the top face of the layer 305. By way of example, the fins 303 extend, when viewed from above, along a first direction, for example along the Y-axis direction.

As an example, the fins 303 extend along the direction of the plane shown in FIG. 3E. For example, the fins have, in section view, a shaped in trapeze, the bottom face of which is not perpendicular to the side faces. For example, the fins 303 are formed in pairs within the substrate 301.

By way of example, the fins have a height ranging from 20 nm to 400 nm, for example a height in the order of 150 nm. As an example, the fins have a width ranging from 2 nm to 30 nm, for example a width ranging from 5 nm to 15 nm, for example a width ranging from 7 nm to 8 nm. By way of example, the fins of the same pair are spaced from 20 nm to 25 nm, for example approximately 22 nm, apart so that the pitch between two fins of a same pair is approximately 30 nm. The fins of two separate pairs are for example spaced from 60 nm to 65 nm, for example approximately 62 nm apart, so that the pitch between two fins of two different pairs is approximately 100 nm.

As an example, the substrate 301 includes within the layer 305 a portion, extending along the Y-axis direction, devoid of pair of fins 303. By way of example, in this portion of the substrate 301 devoid of fins 303, the layer 305 has a thickness equal to the thickness of the layer 305 at the base of fins 303, i.e., equal to the thickness of the layer 305 when it does not include the height of fins 303. By way of example, such a portion is present all 100 to 128 fin pairs.

For example, the substrate 301 includes a semiconductor layer 307. For example, the layer 307 lays on the layer 305, and is in contact with the latter, for example. The layer 307 flushes, for example, a top face of the substrate 301. For example, the semiconductor layer 307 is a layer epitaxially grown from the top face of the layer 305. For example, the layer 307 is made of silicon, e.g., single-crystal silicon, for example doped in-situ with phosphorus atoms. The layer 307 for example includes a plurality of areas 309 and 311. As an example, each fin pair 303 is overlaid according to its length, i.e., along the Y-axis direction, by a series of regions 309 and 311, for example distinct from each other. By way of example, each region 309 or 311 coats both fins of the fin pair 303 it coats. As an example, the same region 309 or 311 does not overlay fins of different pairs.

In the device 300, regions 309 and 311 are arranged, when viewed from above, in the form of an array the columns of which correspond to a series of regions 309 and 311, formed opposite to a same pair of fins 303, and the rows of which are consecutively rows of distinct regions 309 and rows of distinct regions 311.

Each region 311 or 309 preferably extends over the whole height of the layer 307. Each region 311 or 309 thus flushes the top face of the layer 307. For example, each region 311 or 309 is in contact, via its bottom face, with the layer 305.

Regions 309 and 311 are for example doped of a conductivity type, for example the N type. By way of example, regions 309 and 311 include phosphorous atoms.

As an example, regions 309 and 311 are separated two by two by a gate area 313.

For example, gate areas 313 extend along a second direction, for example perpendicular to the first direction, for example the X-axis direction. By way of example, gates 313 extend in the direction of the section plane shown in FIG. 3B. For example, gates 313 are made of metal, e.g., titanium nitride, tantalum nitride, tungsten, or a succession of several layers of one and/or other of these materials.

The device 300 includes a plurality of transistors T formed in and on the substrate 301.

### Transistors T are Fin Field-Effect Transistors FinFETs.

In the example shown in FIGS. 3A-E, each transistor T is defined by a gate 313, a region 311, and a region 309. In this example, the region 309 forms a source region of the transistor, the region 311 forms a drain region D of the transistor, and the gate 313 forms a gate region of the transistor. As that was described with FIG. 2, and as illustrated in the section plane shown in FIG. 3E, a transistor T has its drain D in common with one of its two neighboring transistors and its source S in common with the other of its two neighboring transistors.

Each transistor T is within a unitary memory 101 and a memory cell 101 includes two transistors. Each memory cell further includes a memory element M, preferably formed at least partly facing said transistors, for example facing the drain D region 311 in common to said transistors. Regions 309, unlike regions 311, are for example not overlaid by memory elements M. As an example, within each memory cell, transistors are selecting transistors of the memory element M.

By way of example, the device 300 includes an insulating layer 315 formed on the top face of substrate 305. As an example, the layer 315 is formed between fins 303 of substrate 301. By way of example, the layer 315 has a thickness less than the height of fins 303.

As an example, the insulating layer 315 is made of an insulating material, for example made of an oxide, e.g., silicon oxide.

For example, substrate 301 is overlaid with an interconnecting stack 317. By way of example, the interconnecting stack 317 is formed on the top face of the layer 307 and, more particularly, on the top face of the regions 309 and 311.

As an example, the interconnecting stack 317 is connected to regions 309 and 311 by conductive vias 319. For example, vias 319 are in contact by their bottom faces, with the top face of the layer 307 so that each region 309 and 311 is overlaid by a via 319. By way of example, the interconnecting stack 317 is further connected to other vias 321 coupling, in the portion of substrate 301 devoid of fin 303, the interconnecting stack 317 to gate regions 313.

As an example, vias 319 and 321 are made of a conductive material, e.g., tungsten.

The interconnecting stack 317 is for example made of a series of metal levels including tracks and vias.

The interconnecting stack 317 for example includes a first level 323. The metal level 323 includes for example tracks 323p and vias 323v, coupling tracks 323p to vias 319. By way of example, the vias 323v are in contact, by their top faces, with the bottom face of tracks 323p and, by their bottom faces, with the top face of vias 319.

As an example, in the section plane shown in FIG. 3B, tracks 323p are continuous opposite to each row of regions 309, i.e., a row of regions 309 is overlaid by a single track 323p. For example, in the section plane shown in FIG. 3C, tracks 323p are discontinuous opposite to each of the rows of regions 311, each region 311 being overlaid by a track 323p distinct from the tracks 323p overlaying the neighboring regions 311.

By way of example, in the section plane shown in FIG. 3E, opposite to each pair of fins 303, a track 323p is formed opposite to each of the regions 309 and 311. In this direction, the tracks 323p are distinct. As an example, opposite to the portion of the substrate devoid of fin 303, in the section plane shown in FIG. 3D, tracks 323p couple two by two vias 321. By way of example, a same track 323p couples, along the Y-axis direction, in the portion of the substrate 301 devoid of

fin 303, gates 313 of a same memory cell 101, i.e., gates 313 separated, when viewed from above, by the regions 311.

As an example, vias 323v connect each via 319 and 321 to tracks 323p formed opposite to these vias.

For example, the interconnecting stack 317 includes a second level 325 formed on the level 323, and for example in contact with the metal level 323. For example, the metal level 325 includes tracks 325p and vias 325v, coupling tracks 325p to the metal level 323. By way of example, vias 325 are in contact, via their top faces, with the bottom face of the tracks 325p and, by their bottom faces, with the top face of tracks 323p.

As an example, in the section plane shown in FIG. 3B, tracks 325p are continuous opposite to each row of regions 309 by stopping in line with each of the portions of substrate 301 including no fin 303. In the section plane shown in FIG. 3C, tracks 325p are for example discontinuous opposite to each of the rows of regions 311, each region 311 being overlaid by a track 325p distinct from tracks 325p overlying the neighboring regions 311.

By way of example, in the section plane shown in FIG. 3E, a track 325p is formed opposite to each of the tracks 323p. The tracks 323p and 325p are, in this section plane, similarly patterned. As an example, opposite to the portion of the substrate devoid of fin 303, in the section plane shown in FIG. 3D, the tracks 325p couple two by two vias 321. By way of example, a same track 325p couples, along the Y-axis direction, in the portion of the substrate 301 devoid of fin 303, via the tracks 323p, the gates 313 of a same memory cell 101.

As an example, vias 325v are formed opposite to each of the vias 323v.

For example, the interconnecting stack 317 includes a third level 327 formed on the level 325, and for example in contact with the metal level 325. For example, the metal level 327 includes tracks 327p and vias 327v, coupling the tracks 327p to the metal level 325. By way of example, vias 327v are in contact, via their top faces, with the bottom face of the tracks 327p, and, by their bottom faces, with the top face of the tracks 325p.

As an example, in the section plane shown in FIG. 3B, the tracks 327p are continuous opposite to each row of regions 309 without stopping. By way of example, in this section plane, tracks 327p are connected, by a via 327v, to the tracks 325p formed opposite to the portion of the substrate 201 devoid of fin 303. In the section plane shown in FIG. 3C, the tracks 327p are for example discontinuous opposite to each of the rows of regions 311, each region 311

being overlaid by a track 327p distinct from the tracks 327p overlaying the neighboring regions 311. In this section plane, tracks 327p are connected to the tracks 325p by vias 327v formed opposite to each of the vias 325v.

As an example, in the section plane shown in FIG. 3E, a track 327p is formed opposite to each of the tracks 323p. Tracks 323p and 327p are, in this section plane, similarly patterned. In this section plane, vias 327v coupling the tracks 325p to the tracks 327p are formed opposite to each of the vias 325v. By way of example, opposite to the portion of the substrate devoid of fin 303, in the section plane shown in FIG. 3D, tracks 325p are connected to the tracks 327p, each track 327p being formed on an end of a track 325p. As an example, each track 327p is, when viewed from above, formed between two gates of two neighboring memory cells 101. In this section plane, the tracks 327p and 325p are connected by a via 327v.

By way of example, the interconnecting stack 317 has a thickness of between 200 nm and 800 nm, for example of between 250 nm and 600 nm, e.g., in the order of 350 nm.

The vias and tracks of the metal levels 323, 325, and 327 are, for example, made of a metal material, e.g., copper.

As an example, the vias and conductive tracks are surrounded by insulating layers (not illustrated), for example made of an insulating material.

In this example, the interconnecting stack 317 is formed between the substrate 301 and the memory elements M.

Memory elements M are for example arranged, when viewed from above, according to an array with rows and columns. We speak respectively of word lines extending along the second direction, for example along the X-axis direction, and of bit lines extending along the first direction, i.e., the Y-axis direction. By way of example, each memory element M is located at the crossing of a bit line and a word line.

As an example, the memory elements M illustrated in FIG. 3C are memory elements M of a same word line WL while the memory elements M illustrated in FIG. 3E are memory elements of a same word line BL. In FIG. 3C, only three word lines are illustrated, and in FIG. 3E, only three bit lines are illustrated. In practice, a memory circuit could however include a different number of bit lines and word lines, for example greater than three.

The memory elements M are, in the embodiment shown in FIGS. 3A-E, formed on the top face of the stack 317.

By way of example, the memory elements M are phase-change memory elements M. As an example, each element M includes a layer 329 made of a phase-change material, for example a chalcogenide material, such as an alloy of germanium, antimony and tellurium (GeSbTe) referred to as GST. For example, the layer 329 has a thickness between 30 nm and 100 nm, in the order of 50 nm. For example, the memory elements M of a same bit line include a common layer 329. Thus, the device 300 includes for example as many layers 329 as bit lines. Each layer 329 thus extends along the bit line direction, i.e., Y-axis direction.

In each memory element M, the phase-change material is for example controlled by a heating metal resistive element 331 located under the phase-change material. Element 331 is for example in contact, via its top face, with the bottom face of the layer 329. By way of example, the element 331 is in contact, via its bottom face, with the top face of the interconnecting stack 317, and, more particularly, with the top face of the track 327p. The element 331 is for example laterally surrounded by a layer made of a thermal insulator, not shown. For example, each element 331 is “L”-shaped in the section plane shown in FIG. 3E. As an example, each element has a horizontal part formed in a bottom part of the element 331. The horizontal part of the element 331 is for example in contact with the interconnecting stack 317. By way of example, each element 331 has a vertical part formed in a top part of the element 331 and, more particularly, on and in contact with the horizontal part of the element 331. As an example, the vertical part of the element 331 is in contact with the layer 329. By way of example, the heating element 331 has for example a height between 30 nm and 100 nm, for example in the order of 60 nm. The heating element 331 is for example made of a conductive material, for example made of silicon and titanium nitride (TiSiN).

The layer 329 is for example overlaid by one or more metal levels. In the present embodiment, the layer 329 is overlaid by two metal levels 333 and 335. The metal level 333 is for example formed over the top face of the layer 329, and is for example in contact with the latter. As an example, the metal level 335 is formed on the top face of the metal level 333, and is for example in contact with the latter. By way of example, the metal levels 333 and 335 each include tracks and vias.

As an example, the level 333 includes tracks 333p extending, when viewed from above, along the layer 329. By way of example, the tracks 333p extend along the Y-axis direction only opposite to the layer 329. As an example, the tracks 333p are connected to the layer 329 through vias 333v formed opposite to elements 331. By way of example, in each memory element

M, the metal level 333 and the element 331 respectively form a top electrode and a bottom electrode of the memory element M, and more specifically electrodes of the resistive element with variable resistance formed by the layer 329 of the phase-change material. As an example, memory elements M of a same bit lines are overlaid by a same level 333. In other words, the top electrodes 333 of the memory elements M of a same bit line are connected to each other.

By way of example, the level 335 includes tracks 335p extending, when viewed from above, along tracks 335p. As an example, the tracks 333p and 335p have, when viewed from above, the same geometry. As an example, the tracks 333p and 335p are connected through vias 335v.

Thus, in the embodiment shown in FIGS. 3A-E, each heating element 331 is coupled, via its bottom face, to a region 311 of the layer 307 and this through levels 323, 325, and 327.

In addition, in the embodiment shown in FIGS. 3A-E, the portion of the substrate 301 devoid of fin 303 corresponds to a contact-recovery area of the word lines WL. In this portion, both gates 313 of a same memory cell 201 are connected to a track 327p of the metal level 327. By way of example, the above-mentioned track is common to the whole cells of a same word line.

Further, in the device 300, the regions 309 of a same line extending along the X-axis direction are all connected to each other via the metal level 323 corresponding to the source line. By way of example, in this embodiment, the source lines are, in top view, parallel to the word lines.

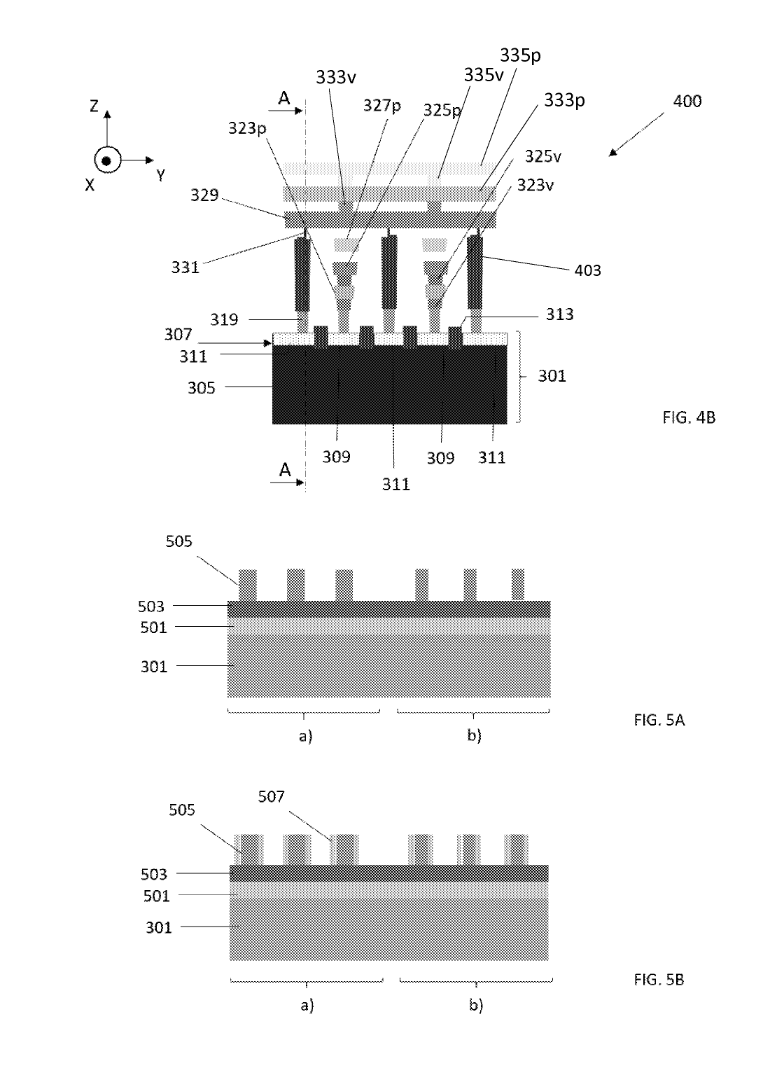

FIG. 4A and FIG. 4B are schematic and partial views of another example 401 of the memory device shown in FIG. 2, FIG. 4A being a view along the same section plane as the view shown in FIG. 3C, and FIG. 4B being a view along the same section plane as the view shown in FIG. 3E.

The device 401 is for example identical to the device 301 illustrated in FIGS. 3A-E, with the difference that, in the device 401, the connection between the element 331 and the vias 319 is performed through a single conductive via 403 instead of through a series of conductive tracks and vias.

Thus, in the embodiment shown in FIGS. 4A-B, each memory element M is electrically connected to the selection transistor T to which it is associated through the conductive via 403 passing through all levels of the interconnecting stack 317. As an example, via 403 further passes through the whole insulating layers of the interconnecting stack 317 and not illustrated in FIGS. 4A-B.

By way of example, the via 403, associated to each memory element M is in contact, via its top face, with the bottom face of the heating resistive element 331 of the memory element M. Each via 403 is for example in contact, by its bottom face, with a conductive via 319, in turn in contact with the top face of the region 311 of the transistor T associated to the memory element M. In other words, within a memory cell 101, the via 403 electrically couples the heating element 331 to the under-lying region 311.

The conductive via 403 is for example made of a metal material. The conductive via 403 is for example made of tungsten. Alternatively, the conductive via is made of cobalt, or copper. The conductive via 403 has for example a width, considered in the plane shown in FIG. 4A and in the plane shown in FIG. 4B, of between 20 nm and 100 nm, for example in the order of 40 nm.

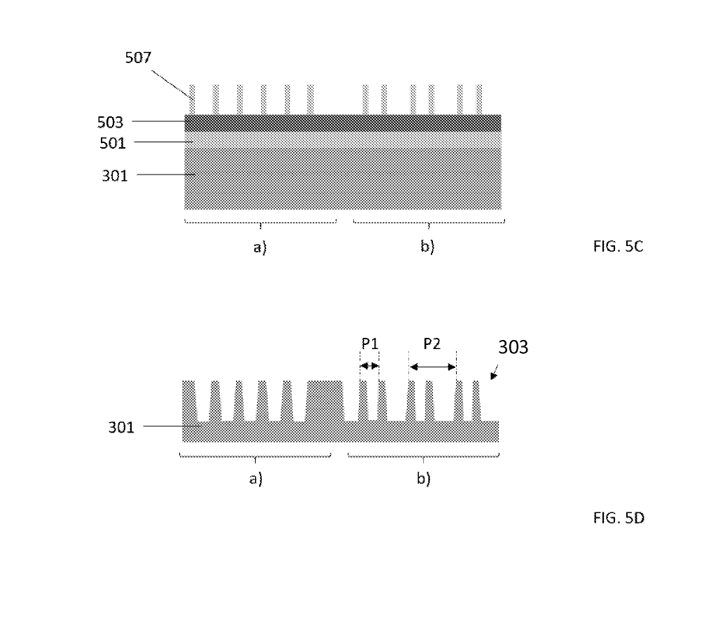

FIG. 5A, FIG. 5B, FIG. 5C, and FIG. 5D are schematic and partial views illustrating steps within an example method for manufacturing the memory devices illustrated in FIGS. 3A-E and in FIGS. 4A-B.

More particularly, FIGS. 5A-D are views illustrating a method for manufacturing pairs of fins of the transistors of the hereinabove memory devices.

In FIGS. 5A-D are illustrated two regions a) and b), region a) corresponding to a method for manufacturing standard fins, with evenly spaced fins, and region b) corresponding to a method for manufacturing pairs of fins within a memory device. Evenly spaced fins are defined as fins that all have the same spacing.

One should understand that in practice, although both regions are represented within a single and same structure, region b) could be manufactured irrespective of region a).

FIG. 5A illustrates, by a partial and schematic section view, a starting structure including the semiconductor substrate 301 overlaid by a first insulating layer 501, a second insulating layer 503, and an amorphous silicon layer 505.

In the structure shown in FIG. 5A, the layer 501 is in contact, via its bottom face, with the top face of the substrate. In addition, in the structure illustrated in FIG. 5A, the layer 503 is in contact, via its bottom face, with the top face of the layer 501. Further, in the structure illustrated in FIG. 5A, the layer 505 is in contact, via its bottom face, with the top face of the layer 503.

By way of example, the layer 501 is made of an oxide, e.g., silicon oxide. As an example, the layer 503 is made of a nitride, e.g., silicon nitride.

The layer 505 includes at the surface of the layer 503 several patterns or pads.

In the region a) shown in FIG. 5A, the pads of the layer 503 have a width of approximately 30 nm, and are all spaced approximately 50 nm apart.

In the region b) shown in FIG. 5A, the pads of the layer 503 have a width of approximately 20 nm, and are all spaced by approximately 60 nm apart.

In the regions a) and b) the pads of the layer 503 have a repetition pitch of approximately 100 nm.

FIG. 5B illustrates a structure obtained at the end of a step for forming spacers on the top face of the structure illustrated in FIG. 5A.

More particularly, during this step, one comes forming, on the flanks of the pads of the layer 505, spacers 507.

Spacers 507 are, for example, formed on the whole regions a) and b).

Spacers 507 are, for example, made of the same material as the layer 501.For example, the spacers 507 are made of silicon oxide.

FIG. 5C illustrates a structure obtained at the end of a step for removing pads of the layer 505, so that only the spacers 507 remain on the top face of the layer 503.

FIG. 5D illustrates a structure obtained at the end of a step for etching the substrate by transferring the pattern formed by spacers 507. In this step, the substrate is etched by forming fins. At the end of this step, in the region a), the fins have a repetition pitch of approximately 40 nm. At the end of this step, in the region b), fins are formed by two, the repetition pitch P1 between two fins close to each other being in the order of 30 nm, and the repetition pitch P2 between two pairs of fins being in the order of 100 nm.

The repetition pitch P1 is then low enough for the epitaxial growths from the fins of a single fin pair to come together to form regions 309 and 311. In addition, the repetition pitch P2 is sufficiently high that the epitaxial growths from the fins of two distinct and adjacent fin pairs do not meet, thus avoiding short circuits between the memory elements of the same bit line.

In one embodiment, region a) and region b) correspond to two parts of the same electronic device. For example, region a) corresponds to a part of the electronic device in which logic circuits are formed, and region b) corresponds to a part of the electronic device in which memory circuits are formed.

In one embodiment, in region a), the fins 303 are regularly distributed over the surface of the region, i.e., the center-to-center distance between two adjacent fins, also known as the fin pitch, is substantially constant over the entire surface of the region.

In one embodiment, in region b), the fins 303 are grouped in pairs. The fins 303 of a same pair are closer together than the fins 303 of two neighboring pairs. The repetition pitch P1 (center-to-center distance between two fins of a same pair) is substantially constant over the entire surface of region b), and the repetition pitch P2 (center-to-center distance between two neighboring pairs of fins) is substantially constant over the entire surface of region b).

Although an example has been described in which, in region b), the repetition pitch P1 is in the order of 30 nm and the repetition pitch P2 is in the order of 100 nm, and in which, in region a), the repetition pitch of the fins is approximately 40 nm, the embodiments are not limited to this particular example.

In one embodiment, the distance between two fins of a same pair in region b) is less than the distance between two adjacent fins in region a). Preferably, the distance between two fins of two adjacent pairs in region b) is greater than the distance between two adjacent fins in region a).

An advantage of the present embodiment is that forming transistors on fin pairs allows size of the electronic devices to be decreased.

Another advantage of the present embodiment is that forming transistors on fin pairs allows the current output by transistors to be increased.

Yet a further advantage of the present embodiment is that connecting source lines in parallel to word lines allows overcrowding within devices to be reduced, and the leakage current within some OFF transistors to be decreased.

Various embodiments and variants have been described. Those skilled in the art will understand that certain features of these embodiments can be combined and other variants will readily occur to those skilled in the art. In particular, one should note that in all examples above-described, drain D and source S conduction nodes of the transistors T could be flipped. Those skilled in the art will know how to adapt the potentials for controlling the memory cell to obtain the desired operation.

Finally, the practical implementation of the embodiments and variants described herein is within the capabilities of those skilled in the art based on the functional description provided hereinabove.

In one embodiment, a memory device (200; 300; 400) includes a plurality of memory cells (101) arranged in an array with word lines (WL) and bit lines (BL), each memory cell (101) including a memory element (M) made of a phase-change material (329) and two fin field-effect transistors (T) for selecting the memory element (M), each transistor (T) including first (D) and second (S) conduction nodes and a gate, the memory element (M) including two terminals, wherein: both transistors of a same memory cell (101) are connected to each other by their first (D) conduction nodes, said first (D) conduction nodes being in turn connected to a first terminal of the memory element (M); the memory elements (M) of a same bit line (BL) are all connected to each other by their second terminals; both transistors (T) of memory cells (101) of a same word line (WL) are all connected to each other, by their gates; each memory cell (101) is connected to two source lines (SL), the two source lines (SL) being connected to the two second (S) conduction nodes of the transistors (T) of the memory cell (101), respectively, the memory cells (101) of a same word line (WL) being connected to the same two source lines (SL), and the memory cells (101) of two consecutive word lines (WL) being connected to a common source line (SL); and each transistor (T) is disposed in and on a pair of two parallel and neighboring fins disposed in a semiconductor substrate (301).

In one embodiment, the transistors (T) of the memory cells of a same bit line (BL) are disposed on and in a same pair of two fins (A).

In one embodiment, the fins of the same pair are spaced from 20 nm to 25 nm apart, for example approximately 22 nm apart.

In one embodiment, the fin pairs, in and on which are disposed the memory cells of two consecutive bit lines, are spaced from 60 nm to 65 nm apart, for example approximately 62 nm apart.

In one embodiment, the phase-change material (329) is made of an alloy of germanium, antimony, and tellurium.

In one embodiment, within each memory cell (101), the memory element (M) is separated from the transistors (T) by an interconnecting stack (317).

In one embodiment, each memory element (M) is connected to the first conduction nodes (D) of both transistors (T) of the same memory cell (M) through a conductive via (403) passing through the interconnecting stack (317).

In one embodiment, the memory element (M) includes a heating metal resistive element (331) disposed under the phase-change material and controlling this same material.

In one embodiment, the source lines (SL) are, in tope view, parallel to word lines (WL).

In one embodiment, the fins are disposed, in a first region (b) of the semiconductor substrate, the device further including other fins, regularly spaced, disposed in a second region (a) of the semiconductor substrate.

In one embodiment, fins of a same pair are closer together than fins of two neighboring pairs.

In one embodiment, a method for manufacturing a device including a plurality of memory cells (101) arranged in an array with word lines (WL) and bit lines (BL), each memory cell (101) including a memory element (M) made of a phase-change material (329) and two fin field-effect transistors (T) for selecting the memory element (M), each transistor (T) including first (D) and second (S) conduction nodes and a gate, the memory element (M) including two terminals (B1, B2), wherein: both transistors of a same memory cell (101) are connected to each other by their first conduction nodes (D), said first conduction nodes (D) being in turn connected to a first terminal (B1) of the memory element (M); the memory elements (M) of a same bit line (BL) are all connected to each other by their second terminals; both transistors (T) of the memory cells (101) in a same word line (WL) are all connected to each other, by their gates; each memory cell (101) is connected to two source lines (SL), the two source lines (SL) being connected to two second conduction nodes (S) of the transistors (T) of the memory cell (101), respectively, the memory cells (101) of a same word line (WL) being connected to the same two source lines (SL), and the memory cells (101) of two consecutive word lines (WL) being connected to a common source line (SL), the method including the steps of: forming fins in a semiconductor substrate, fins being formed by pairs; epitaxially forming a semiconductive layer (307); and doping the semiconductive layer (307) so as to form regions (309, 311) among which first regions (309) correspond to source regions, and second regions (311) correspond to drain regions, a drain region being common to both transistors of the same memory cell and a source region being common to two transistors of two neighboring memory cells (101).

In one embodiment, the formation of the fins is carried out in a first region (b) of the semiconductor substrate, the method further including, during the fins formation step, the formation of further regularly spaced fins in a second region (a) of the semiconductor substrate.

In one embodiment, a method for using a memory device includes, for selecting a memory cell (101) of a first word line (WL) and a first bit line (BL), applying a first non-zero potential on the first bit line (BL) and a zero potential on the other bit lines (BL), applying a second non-zero potential on the first word line (WL) and a zero potential on the other word lines (WL), and applying a zero potential to the two source lines (SL) connected to the memory cells of the first word line and a third non-zero potential to the other source lines (SL).

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A memory device, comprising:
a plurality of memory cells arranged in an array with word lines and bit lines, each memory cell including:
a memory element of a phase-change material and including a first terminal and a second terminal and
two fin field-effect transistors for selecting the memory element, each transistor including first and second conduction nodes and a gate, wherein:
both transistors of a same memory cell are connected to each other by their first conduction nodes, the first conduction nodes being connected to a first terminal of the memory element;
the memory elements of a same bit line are all connected to each other by their second terminals;
both transistors of memory cells of a same word line are all connected to each other by their gates;
each memory cell is connected to two source lines, the two source lines being connected to the two second conduction nodes of the transistors of the memory cell, respectively, the memory cells of a same word line being connected to the same two source lines, and the memory cells of two consecutive word lines being connected to a common source line; and
each transistor is disposed in and on a pair of two parallel and neighboring fins disposed in a semiconductor substrate.

2. The memory device according to claim 1, wherein the transistors of the memory cells of a same bit line are disposed on and in a same pair of two fins.

3. The memory device according to claim 1, wherein the fins of the same pair are spaced from 20 nm to 25 nm apart.

4. The memory device according to claim 1, wherein the fin pairs, in and on which are disposed the memory cells of two consecutive bit lines, are spaced from 60 nm to 65 nm apart.

5. The memory device according to claim 1, wherein the phase-change material is made of an alloy of germanium, antimony, and tellurium.

6. The memory device according to claim 1, wherein, within each memory cell, the memory element is separated from the transistors by an interconnecting stack.

7. The memory device according to claim 6, wherein each memory element is connected to the first conduction nodes of both transistors of the same memory cell through a conductive via passing through the interconnecting stack.

8. The memory device according to claim 1, wherein the memory element includes a heating metal resistive element disposed under the phase-change material and controlling this same material.

9. The memory device according to claim 1, wherein the source lines are, in top view, parallel to word lines.

10. The memory device according to claim 1, wherein the fins are disposed in a first region of the semiconductor substrate,
the device further comprising other fins, regularly spaced, disposed in a second region of the semiconductor substrate.

11. The memory device according to claim 1, wherein fins of a same pair are closer together than fins of two neighboring pairs.

12. A method for manufacturing a device including a plurality of memory cells arranged in an array with word lines and bit lines, each memory cell including a memory element made of a phase-change material and two fin field-effect transistors for selecting the memory element, each transistor comprising first and second conduction nodes and a gate, the memory element including two terminals, wherein:
both transistors of a same memory cell are connected to each other by their first conduction nodes, the first conduction nodes being in turn connected to a first terminal of the memory element;
the memory elements of a same bit line are all connected to each other by their second terminals;
both transistors of the memory cells in a same word line are all connected to each other, by their gates;
each memory cell is connected to two source lines, the two source lines being connected to two second conduction nodes of the transistors of the memory cell, respectively, the memory cells of a same word line being connected to the same two source lines, and the memory cells of two consecutive word lines being connected to a common source line,
the method including the steps of:
forming fins in a semiconductor substrate, fins being formed by pairs;
epitaxially forming a semiconductive layer; and
doping the semiconductive layer so as to form regions among which first regions correspond to source regions, and second regions correspond to drain regions, a drain region being common to both transistors of the same memory cell and a source region being common to two transistors of two neighboring memory cells.

13. The method according to claim 12, wherein the formation of the fins is carried out in a first region of the semiconductor substrate,
the method further comprising, during the fins formation step, the formation of further regularly spaced fins in a second region of the semiconductor substrate.

14. The method according to claim 12, wherein fins of a same pair are closer together than fins of two neighboring pairs.

15. A method, comprising:
applying, in a memory array including a plurality of memory cells arranged in a plurality of bitlines and a plurality of wordlines, a first non-zero potential on a first bit line of the plurality of bitlines of a memory array and a zero potential on the other bit lines of the plurality of bitlines of the memory array, each memory cell including a memory element of a phase-change material and including a first terminal and a second terminal and two fin field-effect transistors for selecting the memory element, each transistor including first and second conduction nodes and a gate, wherein:
both transistors of a same memory cell are connected to each other by their first conduction nodes, the first conduction nodes being connected to a first terminal of the memory element;
the memory elements of a same bit line are all connected to each other by their second terminals;
both transistors of memory cells of a same word line are all connected to each other by their gates;
each memory cell is connected to two source lines, the two source lines being connected to the two second conduction nodes of the transistors of the memory cell, respectively, the memory cells of a same word line being connected to the same two source lines, and the memory cells of two consecutive word lines being connected to a common source line; and
each transistor is disposed in and on a pair of two parallel and neighboring fins disposed in a semiconductor substrate;
applying a second non-zero potential on a first word line of the plurality of wordlines and a zero potential on the other word lines of the plurality of wordlines;
applying a zero potential to two source lines coupled to the memory cells of the first word line and a third non-zero potential to the other source lines.

16. The method according to claim 15, wherein the transistors of the memory cells of a same bit line are disposed on and in a same pair of two fins.

17. The method according to claim 15, wherein the fins of the same pair are spaced from 20 nm to 25 nm apart.

18. The method according to claim 15, wherein the fin pairs, in and on which are disposed the memory cells of two consecutive bit lines, are spaced from 60 nm to 65 nm apart.

19. The method according to claim 15, wherein the phase-change material is made of an alloy of germanium, antimony, and tellurium.

20. The method according to claim 15, wherein fins of a same pair are closer together than fins of two neighboring pairs.
